(19) United States
(12) Patent Application Publication
(10) Pub. No.: US 2016/0372884 A9
(43) Pub. Date: Dec. 22, 2016

(54) High Power Raman-Based Fiber Laser System and Method of Operating the Same

(71) Applicants: Valentin Gapontsev, Worcester, MA (US); Nikolai Platanov, Worcester, MA (US); Alexander Yusim, Boston, MA (US)

(72) Inventors: Valentin Gapontsev, Worcester, MA (US); Nikolai Platanov, Worcester, MA (US); Alexander Yusim, Boston, MA (US)

(73) Assignee: IPG Photonics Corporation, Oxford, MA (US)

(21) Appl. No.: 14/141,897

(22) Filed: Dec. 27, 2013

Related U.S. Application Data
(63) Continuation of application No. PCT/US11/42402, filed on Jun. 29, 2011.

(51) Int. Cl. H01S 3/30; H01S 3/11; H01S 3/0941; H01S 3/067; H01S 5/40; H01S 3/094; H01S 3/16

(52) U.S. Cl. CPC H01S 3/302; H01S 3/094007; H01S 3/094046; H01S 3/1115; H01S 3/1615; H01S 3/06708; H01S 5/4087; H01S 3/0941; H01S 3/0675

(57) ABSTRACT

A fiber Raman laser is configured with a microstructured double clad passive fiber which has an inner cladding receiving and guiding a high intensity pump light. The double-clad passive fiber farther has a eon surrounded by the inner cladding and an outer cladding. An arrangement of air holes is configured to define the inner, waveguiding cladding so that an NA of the latter varies between about 0.25-0.9 allowing this to reduce the diameter of the inner cladding. The passive fiber is characterized by a substantial overlap between the pump light and 1^{st} stokes in the care and further includes an absorber operative to substantially suppress the signal light at the 2^{nd} strokes so that the Ge-doped fiber outputs a SM, bright radiation at up to kW levels.

### BACKGROUND OF THE DISCLOSURE

1. Field of the Disclosure

The present invention relates to scaling of fiber laser output power with high efficiency at any chosen wavelength with a novel cladding pumped Raman fiber laser design.

2. Prior Art

The Raman fiber laser (RFL) has become increasingly popular due to its compactness, raggedness and flexibility, has the potential to be very attractive for industrial and military applications. The RFL is based on stimulated Raman scattering (SRS), a nonlinear optical process whereby photons from a pump beam are converted into lower energy photons of a Stokes beam. In general, an RFL consists of a passive fiber optimized for Raman gain with fiber Bragg gratings (FBGs) on the back end and an output coupler FBG on the front end of the fiber cavity. FBGs can be written directly in a Raman optimized passive fiber with an ultraviolet (UV) laser or written in separate pieces of fiber and then spliced onto the ends of the RFL.

RFLs has two major structural attractive particularities as compared to other types of lasers. One of the advantages of RFLs is that they can output a good quality beam. Particularly, RFLs may produce a single mode output through the use of fibers with single mode and muitimode cores.

The second distinctiveness includes generating a wide range of novel laser wavelengths. For example, altering the wavelength of the pump laser of an RR, modulates the wavelength of the output Stokes beam. Carefully tailoring the gain medium (through proper choice of dopants) provides even more wavelength flexibility. However, single mode pumps for the Raman fiber laser are limited in power; therefore the RFL output power is also limited. Hence, the fiber choice for RFLs is the laser diode pumped double clad fiber laser (DCFL), as disclosed in U.S. Pat. Nos. 5,832,006 and 6,363,087, respectively, both fully incorporated herein by reference. However, the DCFLs operate in a limited wavelength range, and therefore limit the flexibility of the output wavelength.

In a further pump configuration including a diode pumped double-clad pumps for RFL, as known, laser diode pump wavelengths and primary Raman signal overlap i.e., a clad diameter to core diameter ratio is low. The latter limits intensity of pump light which is to be converted. Accordingly, to reach high power outputs, the length of Ge-doped fiber, which is typically used in Raman lasers and amplifiers alone or with other dopants, may be significant. The longer the fiber length, the lower the threshold for nonlinear effects including parasitic Raman Stokes which significantly reduces the efficiency of the primary Stokes light.

A need therefore exists for a RFL operative to output high power bright radiation at the 1^{st} or any other desired stokes wavelength.

### SUMMARY OF THE DISCLOSURE

This need is met by the disclosed RFL structure. The latter includes a Ge-doped fiber core, a pump inner cladding and an outer cladding. The disclosed structure has several aspects advantageously distinguishing it over the known prior art.

In accordance with one aspect, the disclosed Raman laser is characterized by the increased overlap of the pump light supported in the cladding and the 1^{st}stokes (signal) in the core of the disclosed Raman laser. This is attained by the use of a double clad Raman microstructured fiber having a component which increases a numerical aperture of the inner cladding. As a consequence, the diameter of the latter can be decreased to the core's diameter without detrimentally affecting the laser output brightness. The structure may include air holes which define the border between the inner and outer claddings or multi-component glass which can be manufactured with the desired index of refraction.

In accordance with a further aspect, the disclosed RFL is configured with an absorber providing for a distributed loss along the length of the absorber. The absorber includes a doped region surrounding the signal core or located internally within the core and configured to suppress 2^{nd} stokes without meaningful power loss in the 1^{st} stokes Raman light. This is attained by the use of Samarium (“Sm”) dopants which define an absorber that is optimally located either in the core or inner cladding or in both the core and inner cladding.

### BRIEF DESCRIPTION OF THE DRAWINGS

The above and other features, aspects and advantages will become more readily apparent from the specific description disclosed in conjunction with the following drawings, in which:

FIG. 1 is a schematic of one modifications of the disclosed high power Raman fiber laser (“RFL”);

FIG. 2 is a cross-section of a Ge-doped fiber representing one aspect of the disclosed RFL.

FIG. 3 is a schematic of another modification of the disclosed RFL;

FIG. 4 is still another modification of the disclosed RFL;

FIG. 5 illustrates the absorption for 1^{st} and higher stokes of the Raman signal;

FIGS. 6A and 6B illustrate a cross-section of the Ge-doped fiber of FIG. 2 having its core, which is provided with the disclosed absorber, and a refractive index profile, respectively.

FIGS. 7A and 7B illustrate a cross-section of the Ge-doped fiber of FIG. 2 having the disclosed absorber provided in the inner cladding, and a refractive index profile of illustrated fiber, respectively.

FIGS. 8A and 8B illustrate a cross-section of the Ge-doped fiber of FIG. 2 configured with a depressed cladding, which is provided with the disclosed absorber, and a NV-profile of the illustrated fiber, respectively.

FIGS. 9A and 9B illustrate a cross-section of the Ge-doped fiber of FIG. 2 configured as a photonic crystal fiber and a refractive index profile thereof, respectively.

FIG. 10 is a cross-section of still a further modification of the Ge-doped fiber of FIG. 2.

### SPECIFIC DESCRIPTION

Reference will now be made in detail to the disclosed system. The drawings are in simplified form and are far from precise scale. The word “couple” and similar terms do not necessarily denote direct and immediate connections, but also include connections through intermediate elements or devices

The disclosed Raman laser is configured to provide a high power and bright output at the desired wavelength which is attained with a configuration having a high overlap in the core between the pump light and signal in both CW and pulsed regimes. Structurally, thus, the disclosed fiber has a low core-to-cladding ratio. Furthermore, the disclosed Raman laser has a structure configured to output light at the desired wavelength, i.e., the structure which is operative to substantially suppress all undesired Stokes leaving thus only desired Stokes. In particular, the 2^{nd} Stokes and higher order Stokes are suppressed if the 1 Stokes is used for the desired application.

FIG. 1 illustrates a high power Raman laser 10 having one or in more pump laser diode modules 12 which generate pump light coupled into a doped passive fiber 20. As illustrated, an output pump fiber 13 of module 12 is directly spliced to a passive fiber 20 which can be doped with ions of Germanium or Phosphorous. Multiple wavelength selective elements, such as spaced fiber Bragg gratings 16 and 18, are written in doped fiber 20 and define a resonant cavity 14 therebetween.

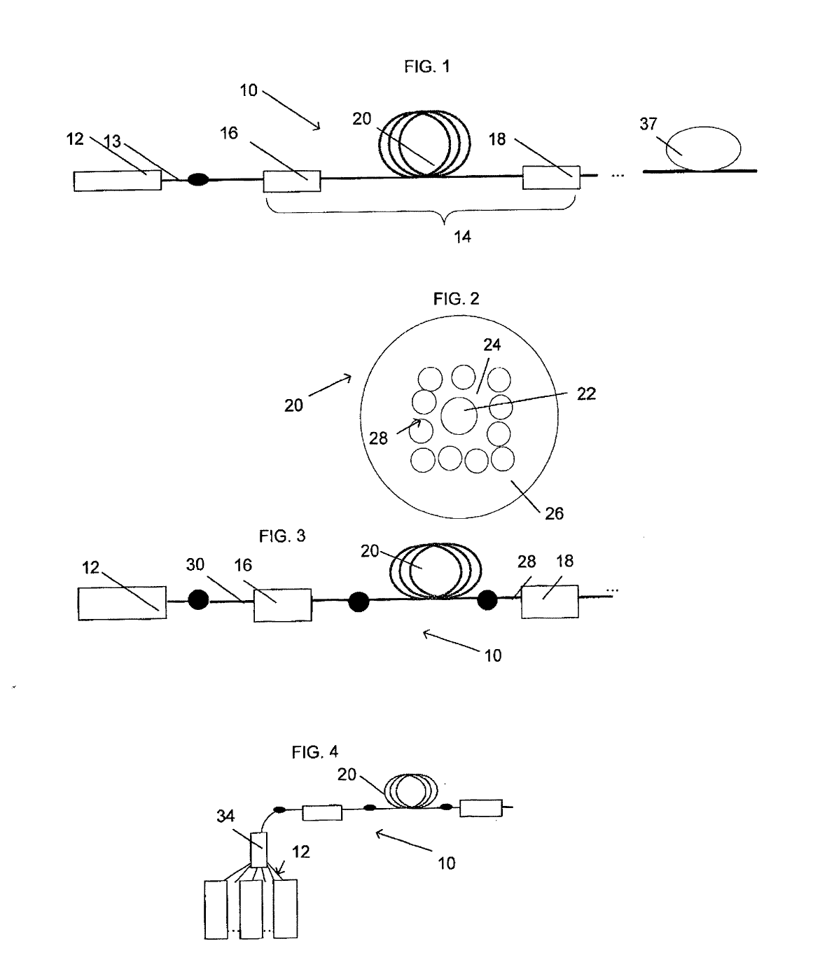

Referring to FIG. 2, disclosed fiber 20 which has a double-clad structure is provided with, for example, a Ge-doped core 22 supporting signal light, an inner waveguiding cladding 24 receiving pump light and an outer cladding 26. The periphery of waveguiding inner cladding 24 is defined by an arrangement of air holes 28. The latter may be arranged symmetrically and asymmetrically with respect to the core axis.

The number of transverse modes supported by a fiber depends from the NA and inner cladding diameter. Since the refractive index of air is nearly 1, the effective NA of outer cladding 26 is high. Therefore, more pump power may be coupled into inner cladding 24 and the latter may be reduced. The reduction of the inner clad diameter translates in a greater overlap between the pump and signal lights in the core. Preferably, the clad to core ratio is about between 2 to 3. As a consequence of the disclosed configuration, the pump light can be converted more efficiently into the signal light along a relatively short Raman fiber length.

FIG. 3 illustrates a modification of schematics shown in FIG. 1. In addition to laser diode module 12 and microstructured SM or MM Ge-doped passive fiber 20, Raman resonator 10 is further configured with input and output single mode (“SM”) passive fibers 30 and 32, respectively. The input and output passive fibers are spliced to respective opposite ends of Ge-doped fiber 20. The FBGs 16 and 18 are written in respective input and output fibers 30 and 32.

FIG. 4 illustrate Raman resonator 10 having a structure similar to the structure of FIG. 3. The difference includes multiple laser diode modules 12 having respective outputs which are combined together in a combiners 34. The laser diodes used in each module may have a multimode (“MM”) or SM configuration depending on pump power needed. The MM diodes are typically more powerful than the SM configuration. Returning to FIGS. 1 and 2, one of numerous applications of Raman resonator 10 may include pumping a fiber amplifier 37. Given only as an example, laser diode module 12 emits radiation in multiple modes at about 935 nm wavelength and of at least 60 W. The diode radiation is coupled into inner cladding 24 of SM Ge-doped fiber 20 and while propagating therealong, is converted into a 1^{st} Stokes signal supported by SM (or MM) core 22 and radiated at about 975 nm wavelength. The Ge-doped fiber 20, for example, may have a core diameter varying between about 5 and 35 μm, inner clad diameter ranging between about 20 and 70 μm and outer clad diameter of about 125 μm. The above-disclosed parameters allow Raman laser 10 to output a bright light reaching a kW level. The fiber amplifier 37 is based on dual clad fibers doped with any of the known rare earth ions and their combinations. For example, amplifier 37 is configured with an Yb-doped fiber having an absorption peak at 975 nm. Pumping amplifier 37 into the peak allows an active Yb-doped fiber to have a relatively short length and, as a consequence, a high threshold fur nonlinearities, such as stimulated Brillion scattering for narrow spectral line configurations or 4-wave mixing for broad line configurations.

As known, one of the limiting factors preventing sealing of SM fiber lasers includes nonlinear effects appearing in a fiber. With the decreased core to cladding ratio, the intensity is also increased. The high intensity, in turn, may cause 2^{nd} and higher parasitic stokes which are substantially suppressed as disclosed immediately below.

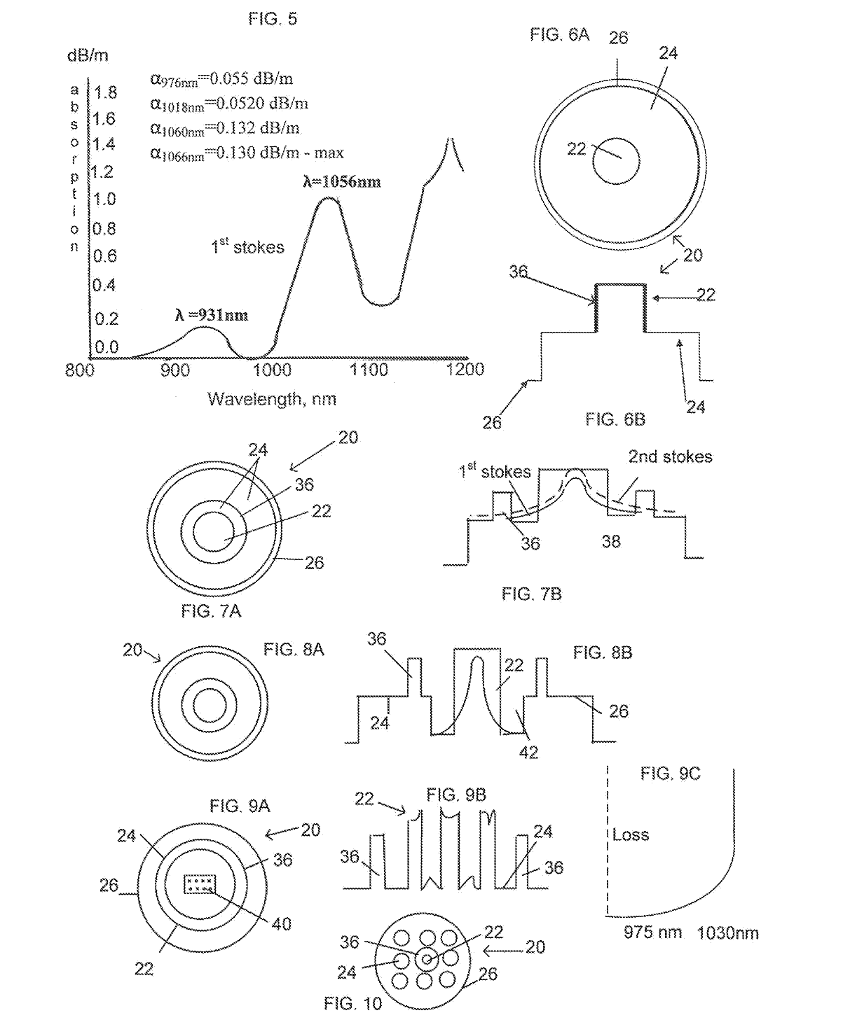

Referring to FIG. 5, RFLs, particularly those operating at high powers, are characterized by the energy transfer from the 1^{st} Stokes to the 2^{nd} Stokes. Accordingly, in order to emit a Raman output at desired wavelengths ranging between about 975 nm and about 977 nm (1^{st} stokes) with the desired high power, the 2^{nd} stokes with a wavelength range between about 1010-1025 nm should be suppressed. Hence, the disclosed Raman resonator is provided with a structure capable of satisfying the above. Particularly, Ge-doped passive fiber 20 includes a samarium-doped region that provides the absorption of signal propagating at the 2^{nd} stokes.

FIGS. 6A and 6B illustrate one of disclosed configurations of absorber 36 provided within SM core 22. Given only as an example, about 50% of dopant concentration includes Ge and about 50% Sm. FIG. 6B illustrates a refractive step index of fiber 20 of FIG. 6A.

FIG. 7A and 7B illustrate a further modification of absorber 36 which is configured with a Sm-doped ring within inner cladding 24 and located in a close vicinity to SM core 22. The Sm ring is so configured that slopes 38 of the fundamental mode of the 2^{nd} stokes overlap with the ring and absorbed there.

FIG. 8A and 8B illustrate still a further modification of Ge-doped fiber 20 of FIG. 2 having a W-profile refractive index. Configured with a depressed region 42, inner cladding 24 has the lowest refractive index. Each stokes may have a fundamental and higher order modes. The configuration of fiber 20 is such that substantially only a fundamental mode of the 1^{st} stokes is supported, whereas the fundamental mode of the 2^{nd} stokes is not supported by core 22 and absorbed in absorber 36 as disclosed above.

FIGS. 9A-9C illustrate a further modification of Ge-doped fiber 20 of FIG. 2 configured as a photonic crystal fiber which has core 22 with a symmetrical arrangement of holes 40. As known, the pitch and dimension of holes 40 may be tailored to prevent propagation of a fundamental mode of 2^{nd} stokes while guiding a fundamental mode of 1^{st} stokes. As an example, FIG. 9C graphically shows substantial losses in the 2^{nd} stokes at a 1018 nm wavelength as compared to those of the 1^{st} stokes at a 975 nm wavelength. The rest of the illustrated structure has absorber 36 provided in inner cladding 24 and air-hole outer cladding 26.

FIG. 10 illustrates a further modification of Ge-doped fiber 20 of FIG. 2 provided with an arrangement of asymmetrically located holes 38 defining inner waveguiding cladding 24. As known, some of pump modes do not cross core 22 and thus are never absorbed. Hence a valuable pump power is not converted. The holes 38 are therefore so arranged that pump modes tend to mix with one another increasing Raman conversion. The rest of the shown configuration is similar to those discussed above and has core 22, absorber 36 within the inner cladding and outer cladding 26 provided with the air hole.

Alternatively, so called multicomponent glasses which can be specifically tailored for the higher NA in order to increase the overlap between the core and cladding, In particular, glass materials can be chosen such as selected to have a large difference and index of refraction between the inner cladding and outer cladding. As an example, such a fiber operates at a 975 nm wavelength using Yb doped fiber core.

Referring to all of the above disclosed schematics, core 22 is configured to guide a single fundamental mode of 1^{st} stokes, However, core 22 may have a MM. configuration. Yet, fiber 20 may he configured so that a mode field diameter of fundamental mode of the 1^{st} stokes can be matched with a MFD of fibers coupled to fiber 22 in a coaxial manner. In this case, the scope of the disclosure fully encompasses the use of MM Ge doped fibers with a step index profile.

The foregoing description and examples have been set forth merely to illustrate the disclosure and are not intended to be limiting. It is understood that using the disclosed technique any higher order stokes may be used as a signal suppressing the unwanted higher order stokes. Accordingly, disclosure should be construed broadly to include all variation within the scope of the appended claims.

1. A Raman fiber laser (“RFL”) comprising:
a passive double-clad fiber having:
a core,
an inner cladding surrounding the core and receiving and guiding the pump light, the pump light being converted into signal light guided along the core at different desired and parasitic wavelengths,
an outer cladding surrounding the inner cladding, and
a component increasing a numerical aperture (“NA”) of the inner cladding to a value within a 0.25-0.8 range, the component being an arrangement of air holes between the inner and outer cladding.

2. The RFL of claim 1, wherein the double-clad fiber is further configured with an absorber operative to induce losses for the signal light at the parasitic wavelength.

3. The RFL of claim 1, wherein the air holes are arranged asymmetrically with respect to a longitudinal fiber axis.

4. The RFL of claim 1, wherein the core and inner cladding are configured with respective diameters defining a ratio ranging between about from 2 to 3 and 1 to 4, respectively.

5. The RFL of claim 1, wherein a diameter of the core ranges between about 5 and 35 μm whereas a diameter of the inner cladding varies between about 20-70 μm and a diameter of the outer cladding is about 125 μm.

6. The RFL of claim 2, wherein the absorber includes ions of Samarium ions.

7. The RFL of claim 6, wherein the core of the passive double clad fiber is configured with the absorber.

8. The RFL of claim 6, wherein the passive doable clad fiber is configured with the inner cladding provided with the absorber which is shaped as a ring surrounding the core so that a fundamental mode of the signal light at the parasitic wavelength overlaps the absorber.

9. The RFL of claim 6, wherein the core of the double-clad fiber is configured with a W profile having the inner cladding which is provided with the absorber, the absorber surrounding the core so that a fundamental mode of the signal light at the parasitic wavelength overlaps the absorber.

10. The RFL of claim 6, wherein the passive-double clad fiber is a photonic crystal fiber, the air holes and absorber being configured to induce losses on a fundamental mode of the signal light at the parasitic wavelength.

11. The RFL of claim 6, wherein the passive-double clad fiber is a photonic bandgap fiber having the core provided with a periodic structure operative to controllably vary an index profile so as to guide only 1 st stokes.

12. The RFL of claim 1, wherein the core is configured to support only a fundamental mode of the signal light propagating along the core at the desired wavelength.

13. The RFL of claim 1, wherein the core has a MM configuration structured to guide substantially only a fundamental mode at the desired wavelength.

14. The RFL of claim 13 further comprising a plurality of MM laser diodes having respective outputs combined into a MM delivery fiber, the delivery fiber being coaxially spliced to the double-clad fiber and configured with a mode field diameter substantially matching that one of the double-clad fiber.

15. The RFL of claim 1 further comprising a plurality of Fiber Bragg gratings spaced apart along the passive double clad fiber to define a cascaded resonant cavity therebetween.

16. The RFL of claim 1 further comprising input and output passive fibers spliced directly to respective opposite ends of the passive double clad fiber, and a plurality of fiber Bragg gratings written in respective input and output passive fibers and defining a resonant cavity therebetween.

17. The RFL of claim 1 further comprising one or more laser diodes operative to output high power pump light in multiple modes at pump wavelength different from the desired and parasitic wavelengths.

18. A Raman fiber laser (“RFL”) comprising:
a passive double-clad fiber having concentrically located core, inner and outer claddings, the core being operative to support light signals at desired and at least one parasitic stoke; and
an absorber provided in the passive double clad fiber and configured to induce losses for the signal light at the parasitic stoke.

19. The RFL of claim 18, wherein the passive double-clad fiber is configured to support single mode or multiple modes.

20. The RFL of claim 18, wherein the passive double-clad fiber is configured with a first arrangement of air holes defining the inner cladding which is configured to guide pump light, the air holes being arranged so that a diameter of the core ranges between about 10 and 20 μm and a diameter of the inner cladding varies between about 30 and 40 μm.
